(19) United States
(12) Patent Application Publication
(10) Pub. No.: US 2021/0105029 A1
(43) Pub. Date: Apr. 8, 2021

(54) RADIO COMMUNICATION DEVICE

(71) Applicant: NEC CORPORATION, Tokyo (JP)

(72) Inventor: Tomohiko HIROSE, Tokyo (JP)

(73) Assignee: NEC CORPORATION, Tokyo (JP)

(21) Appl. No.: 17/016,045

(22) Filed: Sep. 9, 2020

(30) Foreign Application Priority Data
Oct. 3, 2019 (JP) 2019-182652

(51) Int. Cl. H04B 1/04; H03F 3/19

(52) U.S. Cl. CPC H04B 1/0475; H03F 3/19; H03F 2200/165; H03F 2200/451; H03F 2200/336; H04B 2001/0425

(57) ABSTRACT

The radio communication device according to the present invention comprises: a baseband/intermediate frequency band unit that quadrature-modulates an in-phase component and a quadrature component of a digital baseband signal, converts the digital baseband signal into an analog intermediate frequency signal, and outputs the analog intermediate frequency signal; and a radio frequency band unit that generates a radio frequency signal by frequency-converting the analog intermediate frequency signal from the baseband/intermediate frequency band unit, amplifies the generated radio frequency signal, and transmits the amplified radio frequency signal. The baseband/intermediate frequency band unit further includes an analog correction filter that corrects the in-phase component and the quadrature component of the digital baseband signal, based on phase information on an analog filter in the baseband/intermediate frequency band unit and phase information on an analog filter in the radio frequency band unit.

This application is based upon and claims the benefit of priority from Japanese Patent Application No. 2019-182652, filed on Oct. 3, 2019, the disclosure of which is incorporated herein in its entirety by reference.

### TECHNICAL FIELD

The present invention relates to a radio communication device, and particularly relates to distortion compensation of the radio communication device.

### BACKGROUND ART

In a radio communication device of a radio communication system, a factor for distortion of a radio frequency (RF) output is generally due to nonlinearity of input/output characteristics of IF band and RF band power amplifiers. However, influence of a phase characteristic of an analog filter may lead to a distortion characteristic. A standard may not be satisfied, depending on a combination of a product type of a baseband (BB)/intermediate frequency (IF) band unit or a plurality of RF bands.

In general, a linearizer that applies an inverse characteristic to nonlinearity of an amplifier (AMP) exhibits an advantageous effect in improving the distortion characteristic. Increase in capacity is desired in recent years, and this leads to a broadband channel separation (CS) and a high multilevel modulation scheme. Thus, suppression of the distortion characteristic becomes important.

The linearizer is specialized in improving the distortion characteristic of the AMP, and is not for improving a characteristic of the analog filter. Even when adjustment is made in advance during design and evaluation in such a way as to perform inverse correction for a certain combination of the BB/IF band unit and the RF band unit, it may be assumed that no significant improvement is expected for various combinations of the BB/IF band unit and the RF band unit.

Japanese Patent Application Laid-Open No. 2005-20373 (JP2005-20373A) relates to compensation for nonlinear distortion of an analog circuit system that includes a power amplifier in a transmission device. Japanese Patent Application Laid-Open No. 2005-20373 proposes that an optimum characteristic information set value is read out from a memory in an analog amplifier circuit unit and a distortion compensation control unit performs distortion compensation by using the optimum characteristic information set value, in order to adapt to an environmental change and a characteristic change due to repairing, upgrading, and the like of the analog amplifier circuit unit.

However, even when compensation for nonlinear distortion proposed in Japanese Patent Application Laid-Open No. 2005-20373 is applied to a radio communication device constituted of a combination of the BB/IF band unit and the RF band unit, it is difficult to correct distortion attributable to the analog filter in the BB/IF band unit or the analog filter in the RF band unit.

### SUMMARY

An object of the present invention is to provide a radio communication device that suppresses distortion of a radio frequency output in consideration of an analog characteristic of an analog filter and the like.

In order to achieve the object, a radio communication device according to the present invention comprises:

a baseband/intermediate frequency band unit that quadrature-modulates an in-phase component and a quadrature component of a digital baseband signal, converts the digital baseband signal into an analog intermediate frequency signal, and outputs the analog intermediate frequency signal; and

a radio frequency band unit that generates a radio frequency signal by frequency-converting the analog intermediate frequency signal from the baseband/intermediate frequency band unit, amplifies the generated radio frequency signal, and transmits the amplified radio frequency signal, wherein

the radio frequency band unit includes an analog filter and an amplifier that amplifies the generated radio frequency signal,

the baseband/intermediate frequency band unit includes an analog filter, a quadrature modulation unit that quadrature-modulates the in-phase component and the quadrature component of the digital baseband signal, and a linearizer that corrects the in-phase component and the quadrature component of the digital baseband signal to be input to the quadrature modulation unit, in such a way as to compensate for nonlinear distortion of the amplifier in the radio frequency band unit, and

the baseband/intermediate frequency band unit further includes an analog correction filter that corrects the in-phase component and the quadrature component of the digital baseband signal output from the linearizer and to be input to the quadrature modulation unit, based on phase information on the analog filter in the baseband/intermediate frequency band unit and phase information on the analog filter in the radio frequency band unit.

A method of compensating distortion of a radio communication device according to the present invention is a method of compensating distortion of a radio communication device comprising:

a baseband/intermediate frequency band unit that quadrature-modulates an in-phase component and a quadrature component of a digital baseband signal, converts the digital baseband signal into an analog intermediate frequency signal, and outputs the analog intermediate frequency signal; and

a radio frequency band unit that generates a radio frequency signal by frequency-converting the analog intermediate frequency signal from the baseband/intermediate frequency band unit, amplifies the generated radio frequency signal, and transmits the amplified radio frequency signal, wherein

the radio frequency band unit of the radio communication device includes an analog filter and an amplifier that amplifies the generated radio frequency signal, and

the baseband/intermediate frequency band unit of the radio communication device includes an analog filter, a quadrature modulation unit that quadrature-modulates the in-phase component and the quadrature component of the digital baseband signal, and a linearizer that corrects the in-phase component and the quadrature component of the digital baseband signal to be input to the quadrature modulation unit, in such a way as to compensate for nonlinear distortion of the amplifier in the radio frequency band unit,

correcting the in-phase component and the quadrature component of the digital baseband signal output from the linearizer and to be input to the quadrature modulation unit, based on phase information on the analog filter in the baseband/intermediate frequency band unit and phase information on the analog filter in the radio frequency band unit.

### BRIEF DESCRIPTION OF THE DRAWINGS

Exemplary features and advantages of the present invention will become apparent from the following detailed description when taken with the accompanying drawings in which:

FIG. 1 is a block diagram of a radio communication device according to an example embodiment by a superordinate concept;

FIG. 2 is a block diagram of a radio communication device according to a first example embodiment;

FIG. 3 is a graph for describing amplitude/phase information on a BB/IF band unit;

FIG. 4 is a graph for describing amplitude/phase information on an RF band unit;

FIG. 5 is a graph for describing added phase data on the BB/IF band unit and the RF band unit and correction data;

FIG. 6 is a flowchart for describing distortion compensation of the radio communication device in FIG. 2;

FIG. 7 is a block diagram for describing the radio communication device configured according to the first example embodiment; and

FIG. 8 is a block diagram for describing a radio communication device configured according to a second example embodiment.

### EXAMPLE EMBODIMENT

A preferred example embodiment of the present invention will be described in detail with reference to the drawings.

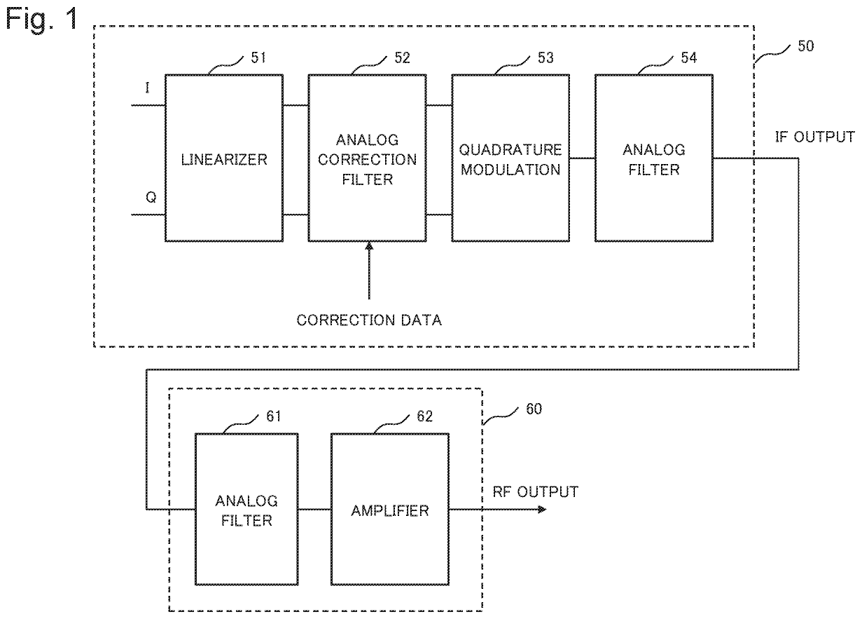

Before a specific example embodiment is described, an example embodiment by a superordinate concept of the present invention will be described. FIG. 1 is a block diagram of a radio communication device according to the example embodiment by the superordinate concept of the present invention. The radio communication device in FIG. 1 includes: a baseband/intermediate frequency band unit 50 and a radio frequency band unit 60. The baseband/intermediate frequency band unit 50 of the radio communication device quadrature-modulates an in-phase component (I) and a quadrature component (Q) of a digital baseband signal, converts the digital baseband signal into an analog intermediate frequency signal (IF signal), and outputs the analog intermediate frequency signal. The radio frequency band unit 60 of the radio communication device generates a radio frequency signal (RF signal) by frequency-converting the analog intermediate frequency signal from the baseband/intermediate frequency band unit 50, amplifies the generated radio frequency signal, and transmits the amplified radio frequency signal.

Further, the radio frequency band unit 60 of the radio communication device in FIG. 1 includes an analog filter 61 and an amplifier 62 that amplifies the generated radio frequency signal.

Further, the baseband/intermediate frequency band unit 50 of the radio communication device in FIG. 1 includes an analog filter 54 and a quadrature modulation unit 53 that quadrature-modulates the in-phase component (I) and the quadrature component (Q) of the digital baseband signal. Further, the baseband/intermediate frequency band unit 50 of the radio communication device in FIG. 1 further includes a linearizer 51 that corrects the in-phase component (I) and the quadrature component (Q) of the digital baseband signal to be input to the quadrature modulation unit 53, in such a way as to compensate for nonlinear distortion of the amplifier 62 in the radio frequency band unit 60.

In addition, the radio communication device in FIG. 1 further includes an analog correction filter 52 that corrects the in-phase component (I) and the quadrature component (Q) of the digital baseband signal output from the linearizer 51 and to be input to the quadrature modulation unit 53, based on phase information on the analog filter 54 in the baseband/intermediate frequency band unit 50 and phase information on the analog filter 61 in the radio frequency band unit 60.

The radio communication device according to the present example embodiment suppresses distortion of an RF output to minimum in consideration of an analog characteristic of an analog filter and the like. In the radio communication device in FIG. 1, the baseband/intermediate frequency band unit 50 and the radio frequency band unit 60 each include an analog filter, and the analog filter has an amplitude characteristic and a phase characteristic. Information on the amplitude characteristic/phase characteristic of the analog filter in the baseband/intermediate frequency band unit 50 and information on the amplitude characteristic/phase characteristic of the analog filter in the radio frequency band unit 60 are stored in advance, and the analog correction filter 52 collects the information on the amplitude characteristic/phase characteristic of the analog filter in the baseband/intermediate frequency band unit 50 and the information on the amplitude characteristic/phase characteristic of the analog filter in the radio frequency band unit 60.

For a necessary band where it is desired to suppress distortion, optimum correction data being an inverse characteristic in which the amplitude/phase are substantially flattened are generated from a characteristic acquired by adding up the amplitude/phase characteristics of the baseband/intermediate frequency band unit 50 and the radio frequency band unit 60. By using the correction data, the analog correction filter 52 corrects the in-phase component (I) and the quadrature component (Q) of the digital baseband signal output from the linearizer 51 and to be input to the quadrature modulation unit 53.

The example embodiment by the superordinate concept is able to achieve a radio communication device that suppresses distortion of a radio frequency output in consideration of an analog characteristic of an analog filter and the like.

The radio communication device in FIG. 1 acquires amplitude/phase information relating to the analog filter in the baseband/intermediate frequency band unit 50 and the analog filter in the radio frequency band unit 60, and digitally inverse-corrects variation caused by the amplitude/phase characteristics of the analog filter in the baseband/intermediate frequency band unit 50 and the analog filter in the radio frequency band unit 60. Consequently, rotation of the phase characteristic of the radio communication device can be cancelled. A more specific example embodiment will be described below.

### First Example Embodiment

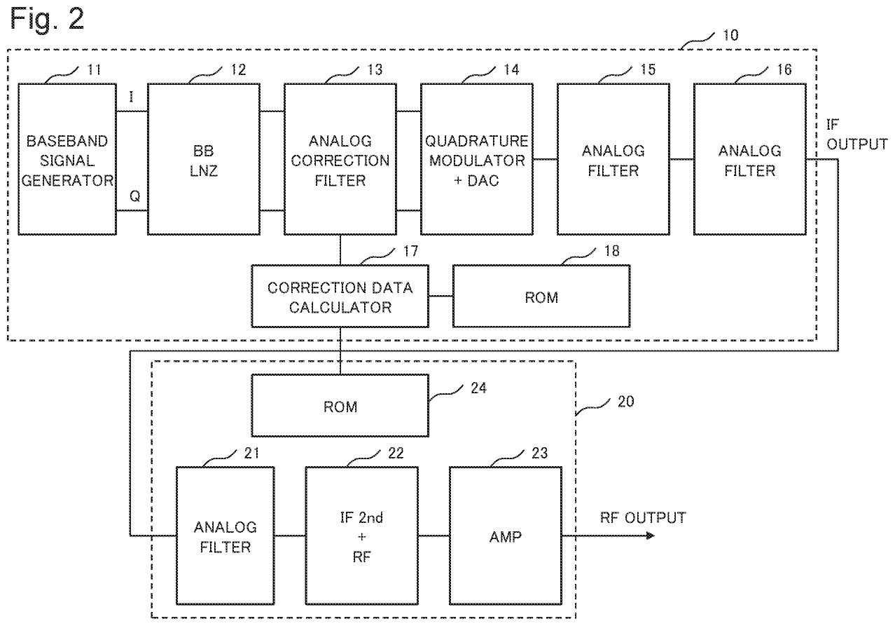

Next, a radio communication device according to a first example embodiment of the present invention will be described. FIG. 2 is a block diagram for describing the radio communication device according to the first example embodiment of the present invention. The radio communication device in FIG. 2 includes a baseband (BB)/intermediate frequency (IF) band unit 10 and a radio frequency (RF) band unit 20.

The BB/IF band unit 10 includes a baseband signal generator 11, a BB linearizer (BB LNZ) 12, an analog correction filter 13, a quadrature modulator+digital-to-analog converter (DAC) 14, an analog filter 15, an analog filter 16, a correction data calculator 17, and a read only memory (ROM) 18.

The RF band unit 20 includes an analog filter 21, an IF 2nd+RF 22, an amplifier 23 (an AMP 23), and a read only memory (ROM) 24.

Elements of the BB/IF band unit 10 will be described in order. The baseband signal generator 11 generates and outputs data of an in-phase component (I) and data of a quadrature component (Q) of a transmission baseband signal.

The BB LNZ 12 is a circuit in which correction of nonlinear distortion of the AMP 23 in the RF band unit 20 is performed in advance in the BB/IF band unit 10, and performs correction on the data of the in-phase component (I) and the data of the quadrature component (Q) of the transmission baseband signal.

The analog correction filter 13 is a circuit in which amplitude/phase correction data are acquired from the correction data calculator 17 and an analog element other than the amplifier is corrected.

The quadrature modulator+DAC 14 includes a quadrature modulation unit and a digital-to-analog converter (DAC) unit, quadrature-modulates the data of the in-phase component (I) and the data of the quadrature component (Q) of the transmission baseband signal being input, and converts the quadrature-modulated digital signal into an analog signal. In recent years, some one-chip DACs can convert a baseband digital signal into an intermediate frequency analog signal.

The analog filter 15 performs a role of cutting off an unwanted wave component generated when the quadrature modulator+DAC 14 generates an IF band signal.

There are a plurality of signals communicating between the BB/IF band unit 10 and the RF band unit 20 in the radio communication device. Among the plurality of signals, the analog filter 16 performs a role of passing only a transmission signal from the analog filter 15. The analog filter 16 outputs an IF OUTPUT (IF output) to the RF band unit 20.

The correction data calculator 17 reads amplitude/phase information from the ROM 18 in the BB/IF band unit 10 and the ROM 24 in the RF band unit 20. In addition, the correction data calculator 17 adds up acquired pieces of amplitude/phase data, and generates an inverse characteristic in which both of the amplitude/phase are flattened, for a necessary frequency band.

The ROM 18 stores information to which amplitude/phase information on the analog filter 15 and the analog filter 16 in the BB/IF band unit 10 are added.

Elements of the RF band unit 20 will be described in order. The analog filter 21 receives an input of the IF OUTPUT (IF output) from the BB/IF band unit 10. There are a plurality of signals communicating between the BB/IF band unit 10 and the RF band unit 20 in the radio communication device. The analog filter 21 performs a role of passing only a transmission signal from the BB/IF band unit 10, as a role similar to the analog filter 16 in the BB/IF band unit 10 described above. Herein, the transmission signal from the BB/IF band unit 10 is a reception signal for the RF band unit 20.

The IF 2nd+RF 22 includes a second intermediate frequency processing unit and a radio frequency processing unit, and frequency-converts an IF band signal from several GHz to several tens GHz.

The AMP 23 indicates a high-power analog AMP, and transmits a signal as an RF OUTPUT (RF output) while controlling power with a variable attenuator or the like.

The ROM 24 stores amplitude/phase information on the analog filter 21 in the RF band unit 20.

### Operation of Example Embodiment

Next, an operation of the radio communication device according to the present example embodiment, particularly, a distortion compensation operation will be described.

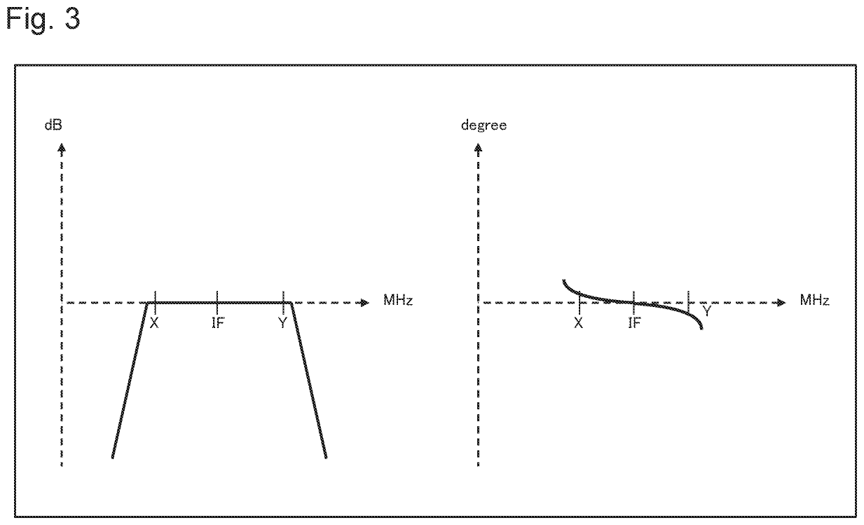

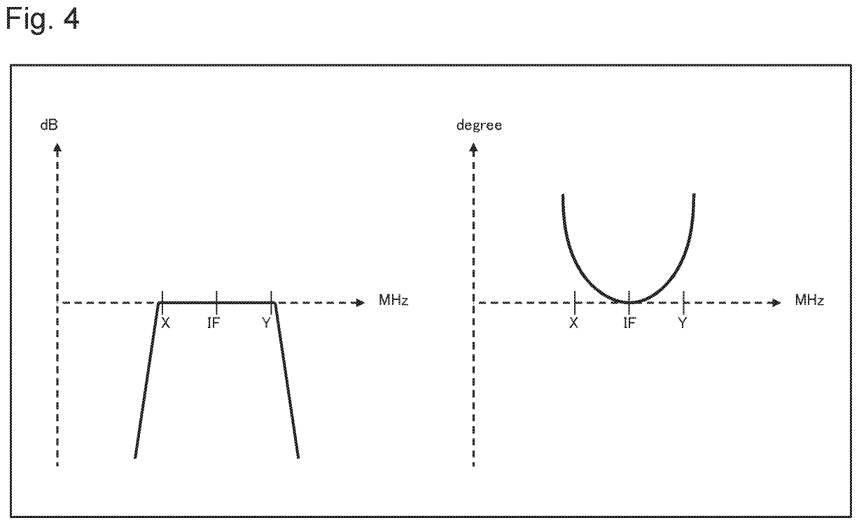

The amplitude/phase information stored in the ROM 18 in the BB/IF band unit 10 is assumed as illustrated in a graph in FIG. 3. The amplitude/phase information stored in the ROM 24 in the RF band unit 20 is assumed as illustrated in a graph in FIG. 4. In FIGS. 3 and 4, a frequency X (MHz) that is on a low-band side with respect to an intermediate frequency IF (MHz) and a frequency Y (MHz) that is on a high-band side with respect to the intermediate frequency IF (MHz) are illustrated as rough indications.

Normally, designing and evaluation of the radio communication device are proceeded in such a way that both of the BB/IF band unit 10 and the RF band unit 20 have the amplitude/phase information within a designated value. However, this specification is merely for the BB/IF band unit 10 alone or for the RF band unit 20 alone, and may be a strict condition, depending on a combination of the BB/IF band unit 10 and the RF band unit 20. Added phase information acquired from FIGS. 3 and 4 comes in a mutually intensifying direction on a frequency-X side being the low-band side when seen from the intermediate frequency IF, but comes in a cancelling direction on a frequency-Y side being the high-band side. In this case, the frequency-X side being the low-band side when seen from the intermediate frequency IF is led to deterioration of a distortion characteristic.

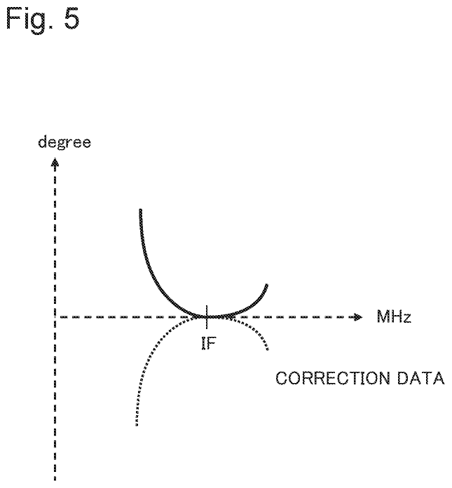

Only once after power of the radio communication device is turned on and communication between the BB/IF band unit 10 and the RF band unit 20 is established, the correction data calculator 17 according to the present example embodiment acquires the amplitude/phase information from the ROM 18 in the BB/IF band unit 10 and the ROM 24 in the RF band unit 20. The correction data calculator 17 adds up the acquired pieces of amplitude/phase data, and generates an inverse characteristic in which both of the amplitude/phase are flattened, for a range of necessary frequency band. More specifically, the correction data calculator 17 adds up the acquired pieces of amplitude/phase data, acquires phase information illustrated by a solid line in FIG. 5, and then generates correction data being an inverse characteristic illustrated by a dotted line in FIG. 5. An existing technique can be used for generation of the correction data.

The analog correction filter 13 acquires the correction data being the inverse characteristic from the correction data calculator 17. Based on the correction data generated by the correction data calculator 17, the analog correction filter 13 performs inverse correction for an output of the BB LNZ 12 in the BB/IF band unit 10. Specifically, the analog correction filter 13 in the BB/IF band unit 10 corrects an analog element other than the amplifier, based on the correction data generated by the correction data calculator 17. Consequently, it becomes possible to minimize influence of amplitude/phase characteristics, especially, a phase characteristic of an IF band filter in the BB/IF band unit 10 and the RF band unit 20.

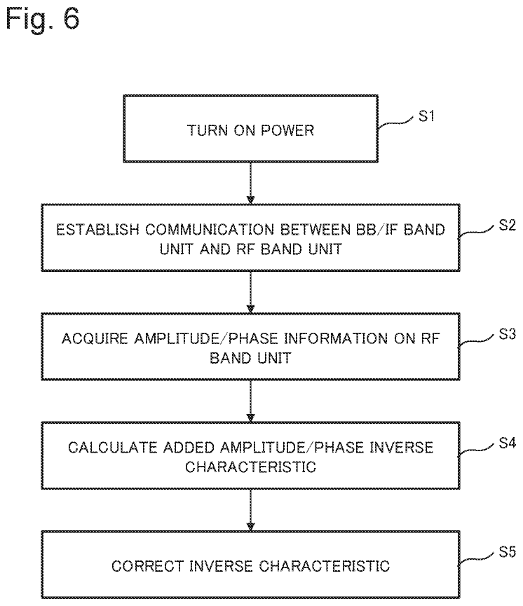

Distortion compensation flow of the radio communication device according to the present example embodiment will be described again with reference to a flowchart in FIG. 6. After power of the radio communication device is turned on (Step S1), communication between the BB/IF band unit 10 and the RF band unit 20 is established (Step S2). Then, the correction data calculator 17 in the BB/IF band unit 10 acquires amplitude/phase information stored in the ROM 24 of the RF band unit 20 (Step S3). At this time, the correction data calculator 17 in the BB/IF band unit 10 also acquires amplitude/phase information stored in the ROM 18 of the BB/IF band unit 10. The correction data calculator 17 in the BB/IF band unit 10 calculates an inverse characteristic from amplitude/phase information acquired by adding up the amplitude/phase information from the ROM 18 and the amplitude/phase information from the ROM 24 (Step S4), and generates correction data being the inverse characteristic. The analog correction filter 13 in the BB/IF band unit 10 reflects correction using the inverse characteristic, based on the correction data generated by the correction data calculator 17 (Step S5).

### Advantageous Effect of Example Embodiment

The radio communication device according to the present example embodiment acquires the amplitude/phase information stored in the ROM 18 of the BB/IF band unit 10 and relating to the analog filter and the amplitude/phase information stored in the ROM 24 of the RF band unit 20 and relating to the analog filter, and digitally inverse-corrects variation caused by the amplitude/phase characteristics of the BB/IF band unit 10 and the RF band unit 20. Consequently, rotation of the phase characteristic of the radio communication device can be cancelled. In particular, even in various kinds of combinations of the BB/IF band unit 10 and the RF band unit 20, the radio communication device with an RF output of a satisfactory distortion characteristic that sufficiently satisfies a standard can be achieved by cancelling rotation of the phase characteristic of the analog filter.

### Second Example Embodiment

Next, a radio communication device according to a second example embodiment of the present invention will be described. A specific description of a matter similar to the first example embodiment will be omitted. The present example embodiment relates to a way of thinking a combination of product types of BB/IF band units and RF band units constituting the radio communication device, and amplitude/phase information stored in a ROM 18 of a BB/IF band unit 10 and amplitude/phase information stored in a ROM 24 of an RF band unit 20.

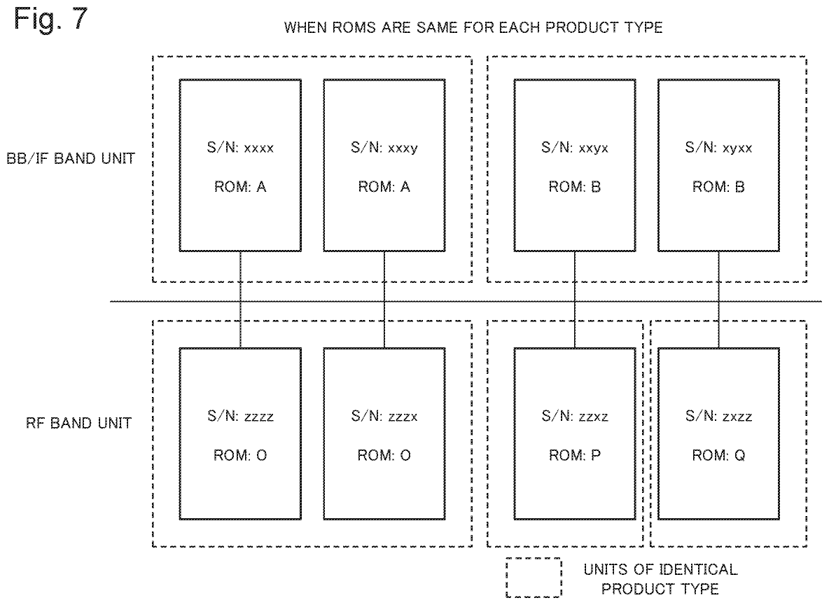

According to the above-described first example embodiment, it is assumed that, when the product types of the BB/IF band units and the RF band units are the same, the amplitude/phase information to be stored in the ROM 18 and the amplitude/phase information to be stored in the ROM 24 are the same. FIG. 7 is a block diagram illustrating a four-system radio communication device, and indicates that units enclosed by a dotted line are units of an identical product type. Among the BB/IF band units in FIG. 7, a serial number (S/N: xxxx) and a serial number (S/N: xxxy) are an identical product type, and ROMs of the BB/IF band units store data A in common. A serial number (S/N: xxyx) and a serial number (S/N: xyxx) are an identical product type, and ROMs of the BB/IF band units store data B in common.

Among the RF band units in FIG. 7, a serial number (S/N: zzzz) and a serial number (S/N: zzzx) are an identical product type, and ROMs of the RF band units store data O in common. A ROM of a serial number (S/N: zzxz) stores data P, and a ROM of a serial number (S/N: zxzz) stores data Q.

In contrast to this, in the radio communication device according to the present example embodiment, even when the product types of the BB/IF band units and the product types of the RF band units are the same, optimization is performed on an individual unit basis for the BB/IF band units and the RF band units. The radio communication device according to the present example embodiment is achieved by measuring a filter characteristic when the BB/IF band units and the RF band units are produced and inspected, and writing, for each unit of the BB/IF band units and the RF band units, amplitude/phase information for optimum correction with respect to amplitude/phase information.

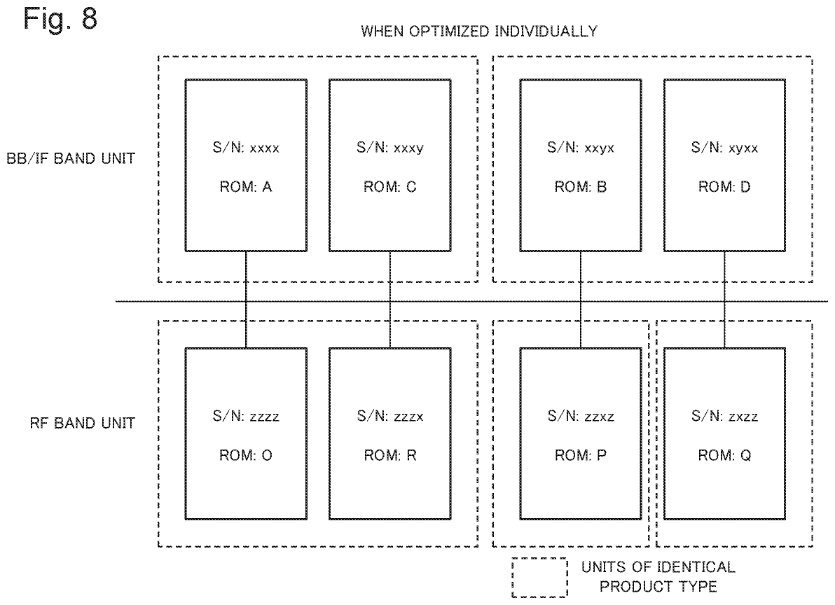

FIG. 8 is a block diagram illustrating a four-system radio communication device similar to that in FIG. 7, and indicates that units enclosed by a dotted line are units of an identical product type. Among the BB/IF band units in FIG. 8, although a serial number (S/N: xxxx) and a serial number (S/N: xxxy) are an identical product type, a ROM of the serial number (S/N: xxxx) stores data A and a ROM of the serial number (S/N: xxxy) stores data C. Among the BB/IF band units in FIG. 8, although a serial number (S/N: xxyx) and a serial number (S/N: xyxx) are an identical product type, a ROM of the serial number (S/N: xxyx) stores data B and a ROM of the serial number (S/N: xyxx) stores data D. Among the RF band units in FIG. 8, although a serial number (S/N: zzzz) and a serial number (S/N: zzzx) are an identical product type, a ROM of the serial number (S/N: zzzz) stores data O and a ROM of the serial number (S/N: zzzx) stores data R. Among the RF band units in FIG. 8, a ROM of a serial number (S/N: zzxz) stores data P, and a ROM of a serial number (S/N: zxzz) stores data Q.

### Advantageous Effect of Example Embodiment

The radio communication device according to the present example embodiment acquires the amplitude/phase information stored in the ROM of the BB/IF band unit and the amplitude/phase information stored in the ROM of the RF band unit, and digitally inverse-corrects variation caused by the amplitude/phase characteristics of the BB/IF band unit and the RF band unit, similarly to the first example embodiment. Consequently, rotation of the phase characteristic of the radio communication device can be cancelled, similarly to the first example embodiment. In various kinds of combinations of the BB/IF band unit and the RF band unit, the radio communication device with an RF output of a satisfactory distortion characteristic that sufficiently satisfies a standard can be achieved by cancelling rotation of the phase characteristic of the analog filter.

Further, according to the present example embodiment, the amplitude/phase information is stored in the ROM on an individual unit basis, even for units of an identical product type among the BB/IF band units and the RF band units. Consequently, even for units of an identical product type, variation caused by the amplitude/phase characteristics of the BB/IF band unit and the RF band unit can be digitally inverse-corrected with reference to the amplitude/phase information reflecting characteristics of individual units. Consequently, rotation of the phase characteristic of the radio communication device can be cancelled with higher precision than the first example embodiment.

While the preferred example embodiments of the present invention have been described, the present invention is not limited to these example embodiments. Various modifications may be made as far as such modifications lie within the scope of the invention defined in the claims, and it is needless to say that such modifications lie in the scope of the present invention.

The whole or part of the example embodiments disclosed above can be described as, but not limited to, the following supplementary notes.

(Supplementary note 1) A radio communication device including:

a baseband/intermediate frequency band unit that quadrature-modulates an in-phase component and a quadrature component of a digital baseband signal, converts the digital baseband signal into an analog intermediate frequency signal, and outputs the analog intermediate frequency signal; and

a radio frequency band unit that generates a radio frequency signal by frequency-converting the analog intermediate frequency signal from the baseband/intermediate frequency band unit, amplifies the generated radio frequency signal, and transmits the amplified radio frequency signal, wherein

the radio frequency band unit includes an analog filter and an amplifier that amplifies the generated radio frequency signal,

the baseband/intermediate frequency band unit includes an analog filter, a quadrature modulation unit that quadrature-modulates the in-phase component and the quadrature component of the digital baseband signal, and a linearizer that corrects the in-phase component and the quadrature component of the digital baseband signal to be input to the quadrature modulation unit, in such a way as to compensate for nonlinear distortion of the amplifier in the radio frequency band unit, and

the baseband/intermediate frequency band unit further includes an analog correction filter that corrects the in-phase component and the quadrature component of the digital baseband signal output from the linearizer and to be input to the quadrature modulation unit, based on phase information on the analog filter in the baseband/intermediate frequency band unit and phase information on the analog filter in the radio frequency band unit.

(Supplementary note 2) The radio communication device according to supplementary note 1, wherein

the baseband/intermediate frequency band unit further includes a correction data calculator that gives inverse correction data to the analog correction filter, based on phase information on the analog filter in the baseband/intermediate frequency band unit and phase information on the analog filter in the radio frequency band unit.

(Supplementary note 3) The radio communication device according to supplementary note 1 or 2, wherein

the baseband/intermediate frequency band unit further includes a memory that stores phase information on the analog filter in the baseband/intermediate frequency band unit.

(Supplementary note 4) The radio communication device according to any one of supplementary notes 1 to 3, wherein

the radio frequency band unit further includes a memory that stores phase information on the analog filter in the radio frequency band unit.

(Supplementary note 5) The radio communication device according to any one of supplementary notes 1 to 4, further including

a plurality of baseband/intermediate frequency band units or a plurality of radio frequency band units, wherein

at least either the plurality of baseband/intermediate frequency band units or the plurality of radio frequency band units include units of an identical product type, and

memories that store the phase information of the units of an identical product type store same data.

(Supplementary note 6) The radio communication device according to any one of supplementary notes 1 to 4, further including

a plurality of baseband/intermediate frequency band units or a plurality of radio frequency band units, wherein

at least either the plurality of baseband/intermediate frequency band units or the plurality of radio frequency band units include units of an identical product type, and

memories that store the phase information of the units of an identical product type store mutually different data.

(Supplementary note 7) A method of compensating distortion of a radio communication device, the radio communication device comprising:

a baseband/intermediate frequency band unit that quadrature-modulates an in-phase component and a quadrature component of a digital baseband signal, converts the digital baseband signal into an analog intermediate frequency signal, and outputs the analog intermediate frequency signal; and

a radio frequency band unit that generates a radio frequency signal by frequency-converting the analog intermediate frequency signal from the baseband/intermediate frequency band unit, amplifies the generated radio frequency signal, and transmits the amplified radio frequency signal, wherein

the radio frequency band unit of the radio communication device includes an analog filter and an amplifier that amplifies the generated radio frequency signal, and

the baseband/intermediate frequency band unit of the radio communication device includes an analog filter, a quadrature modulation unit that quadrature-modulates the in-phase component and the quadrature component of the digital baseband signal, and a linearizer that corrects the in-phase component and the quadrature component of the digital baseband signal to be input to the quadrature modulation unit, in such a way as to compensate for nonlinear distortion of the amplifier in the radio frequency band unit,

correcting the in-phase component and the quadrature component of the digital baseband signal output from the linearizer and to be input to the quadrature modulation unit are corrected based on phase information on the analog filter in the baseband/intermediate frequency band unit and phase information on the analog filter in the radio frequency band unit.

(Supplementary note 8) The method of compensating distortion of the radio communication device according to supplementary note 7, further including

generating inverse correction data, based on phase information on the analog filter in the baseband/intermediate frequency band unit and phase information on the analog filter in the radio frequency band unit, in order to correct the in-phase component and the quadrature component of the digital baseband signal output from the linearizer and to be input to the quadrature modulation unit.

(Supplementary note 9) The method of compensating distortion of the radio communication device according to supplementary note 7 or 8, wherein

the baseband/intermediate frequency band unit stores phase information on the analog filter in the baseband/intermediate frequency band unit.

(Supplementary note 10) The method of compensating distortion of the radio communication device according to any one of supplementary notes 7 to 9, wherein

the radio frequency band unit stores phase information on the analog filter in the radio frequency band unit.

(Supplementary note 11) The method of compensating distortion of the radio communication device according to any one of supplementary notes 7 to 10, the radio communication device including a plurality of baseband/intermediate frequency band units or a plurality of radio frequency band units, wherein

at least either the plurality of baseband/intermediate frequency band units or the plurality of radio frequency band units include units of an identical product type, and

memories that store the phase information of the units of an identical product type store same data.

(Supplementary note 12) The method of compensating distortion of the radio communication device according to any one of supplementary notes 7 to 10, the radio communication device including a plurality of baseband/intermediate frequency band units or a plurality of radio frequency band units, wherein

at least either the plurality of baseband/intermediate frequency band units or the plurality of radio frequency band units include units of an identical product type, and

memories that store the phase information of the units of an identical product type store mutually different data.

The previous description of embodiments is provided to enable a person skilled in the art to make and use the present invention. Moreover, various modifications to these example embodiments will be readily apparent to those skilled in the art, and the generic principles and specific examples defined herein may be applied to other embodiments without the use of inventive faculty. Therefore, the present invention is not intended to be limited to the example embodiments described herein but is to be accorded the widest scope as defined by the limitations of the claims and equivalents.

Further, it is noted that the inventor's intent is to retain all equivalents of the claimed invention even if the claims are amended during prosecution.

1. A radio communication device comprising:
a baseband/intermediate frequency band unit that quadrature-modulates an in-phase component and a quadrature component of a digital baseband signal, converts the digital baseband signal into an analog intermediate frequency signal, and outputs the analog intermediate frequency signal; and
a radio frequency band unit that generates a radio frequency signal by frequency-converting the analog intermediate frequency signal from the baseband/intermediate frequency band unit, amplifies the generated radio frequency signal, and transmits the amplified radio frequency signal, wherein
the radio frequency band unit includes an analog filter and an amplifier that amplifies the generated radio frequency signal,
the baseband/intermediate frequency band unit includes an analog filter, a quadrature modulation unit that quadrature-modulates the in-phase component and the quadrature component of the digital baseband signal, and a linearizer that corrects the in-phase component and the quadrature component of the digital baseband signal to be input to the quadrature modulation unit, in such a way as to compensate for nonlinear distortion of the amplifier in the radio frequency band unit, and
the baseband/intermediate frequency band unit further includes an analog correction filter that corrects the in-phase component and the quadrature component of the digital baseband signal output from the linearizer and to be input to the quadrature modulation unit, based on phase information on the analog filter in the baseband/intermediate frequency band unit and phase information on the analog filter in the radio frequency band unit.

2. The radio communication device according to claim 1, wherein
the baseband/intermediate frequency band unit further includes a correction data calculator that gives inverse correction data to the analog correction filter, based on phase information on the analog filter in the baseband/intermediate frequency band unit and phase information on the analog filter in the radio frequency band unit.

3. The radio communication device according to claim 1, wherein
the baseband/intermediate frequency band unit further includes a memory that stores phase information on the analog filter in the baseband/intermediate frequency band unit.

4. The radio communication device according to claim 1, wherein
the radio frequency band unit further includes a memory that stores phase information on the analog filter in the radio frequency band unit.

5. The radio communication device according to claim 1, further comprising
a plurality of baseband/intermediate frequency band units or a plurality of radio frequency band units, wherein
at least either the plurality of baseband/intermediate frequency band units or the plurality of radio frequency band units include units of an identical product type, and
memories that store the phase information of the units of an identical product type store same data.

6. The radio communication device according to claim 1, further comprising
a plurality of baseband/intermediate frequency band units or a plurality of radio frequency band units, wherein
at least either the plurality of baseband/intermediate frequency band units or the plurality of radio frequency band units include units of an identical product type, and
memories that store the phase information of the units of an identical product type store mutually different data.

7. A method of compensating distortion of a radio communication device, the radio communication device comprising:
a baseband/intermediate frequency band unit that quadrature-modulates an in-phase component and a quadrature component of a digital baseband signal, converts the digital baseband signal into an analog intermediate frequency signal, and outputs the analog intermediate frequency signal; and
a radio frequency band unit that generates a radio frequency signal by frequency-converting the analog intermediate frequency signal from the baseband/intermediate frequency band unit, amplifies the generated radio frequency signal, and transmits the amplified radio frequency signal, wherein
the radio frequency band unit of the radio communication device includes an analog filter and an amplifier that amplifies the generated radio frequency signal, and
the baseband/intermediate frequency band unit of the radio communication device includes an analog filter, a quadrature modulation unit that quadrature-modulates the in-phase component and the quadrature component of the digital baseband signal, and a linearizer that corrects the in-phase component and the quadrature component of the digital baseband signal to be input to the quadrature modulation unit, in such a way as to compensate for nonlinear distortion of the amplifier in the radio frequency band unit,
correcting the in-phase component and the quadrature component of the digital baseband signal output from the linearizer and to be input to the quadrature modulation unit, based on phase information on the analog filter in the baseband/intermediate frequency band unit and phase information on the analog filter in the radio frequency band unit.

8. The method of compensating distortion of the radio communication device according to claim 7, further comprising
generating inverse correction data, based on phase information on the analog filter in the baseband/intermediate frequency band unit and phase information on the analog filter in the radio frequency band unit, in order to correct the in-phase component and the quadrature component of the digital baseband signal output from the linearizer and to be input to the quadrature modulation unit.

9. The method of compensating distortion of the radio communication device according to claim 7, wherein
the baseband/intermediate frequency band unit stores phase information on the analog filter in the baseband/intermediate frequency band unit.

10. The method of compensating distortion of the radio communication device according to claim 7, wherein
the radio frequency band unit stores phase information on the analog filter in the radio frequency band unit.

11. The method of compensating distortion of the radio communication device according to claim 7, the radio communication device including a plurality of baseband/intermediate frequency band units or a plurality of radio frequency band units, wherein
at least either the plurality of baseband/intermediate frequency band units or the plurality of radio frequency band units include units of an identical product type, and
memories that store the phase information of the units of an identical product type store same data.

12. The method of compensating distortion of the radio communication device according to claim 7, the radio communication device including a plurality of baseband/intermediate frequency band units or a plurality of radio frequency band units, wherein
at least either the plurality of baseband/intermediate frequency band units or the plurality of radio frequency band units include units of an identical product type, and
memories that store the phase information of the units of an identical product type store mutually different data.
